(19) United States
(12) Patent Application Publication
(10) Pub. No.: US 2026/0213136 A1
(43) Pub. Date: Jul. 23, 2026

(54) ELECTROSTATIC CHUCK WITH LIGHT-UP RESISTANT FLOW ENHANCEMENT PLUG

(71) Applicant: Applied Materials, Inc., Santa Clara, CA (US)

(72) Inventors: Michael R. RICE, Pleasanton, CA (US); Mayra RAMIREZ, Santa Clara, CA (US); Shahid RAUF, Pleasanton, CA (US); Vladimir KNYAZIK, Santa Clara, CA (US); Chien-Min LIAO, San Jose, CA (US); Marc SHULL, San Jose, CA (US); Andy KC CHUANG, Santa Clara, CA (US); Tom K. CHO, Los Altos, CA (US); Bruce ALGER, Santa Clara, CA (US)

(21) Appl. No.: 19/073,823

(22) Filed: Mar. 7, 2025

Related U.S. Application Data
(60) Provisional application No. 63/746,557, filed on Jan. 17, 2025.

(51) Int. Cl. H01J 37/32

(52) U.S. Cl. CPC H01J 37/32715; H01J 37/3244; H10P 72/722; H01J 2237/2007

(57) ABSTRACT

Flow enhancement plugs and electrostatic chucks having the same are disclosed herein that that inhibit gas light-up while providing excellent flow conductance for the delivery of backside gases to the substrate support surface of the electrostatic chuck. The flow enhancement plugs advantageously prevents line of sight passage through the plug. The flow enhancement plugs described herein have high conductance flow structures selected from one, two or all of a network of engineered gas passages, external gas passages and internal gas passages. As a result, the high conductance flow structures of the flow enhancement plugs disclosed herein beneficially have a conductance that is much lower than conventional porous plug.

### RELATED APPLICATIONS

This application claims benefit from U.S. Provisional Application Ser. No. 63/746,557, filed Jan. 17, 2025, the contents of which is incorporated by reference in its entirety.

### BACKGROUND

### Field

Implementations described herein generally relate to a substrate support pedestal and more particularly to a substrate support pedestal having an electrostatic chuck that includes a light-up resistant flow enhancement plug.

### Description of the Related Art

Substrate support pedestals are widely used to support substrates within semiconductor processing systems during processing. One particular type of substrate support pedestal includes a ceramic electrostatic chuck mounted on a cooling base. Electrostatic chucks generally retain the substrate in a stationary position during processing. Electrostatic chucks contain one or more embedded electrodes within a ceramic body. As an electrical potential is applied between the electrodes and a substrate disposed on the ceramic body, an electrostatic attraction is generated, which holds the substrate against a support surface of the ceramic body. The force generated may have a capacitive effect due to a potential difference between the substrate and the electrodes or, in the case of ceramic bodies comprised of semiconducting materials having a relatively low resistivity, which allow charge migration within the ceramic body to the surface approximate the substrate, a Johnsen-Rahbek effect. Electrostatic chucks utilizing capacitive and Johnsen-Rahbek attractive forces are commercially available from a number of sources.

To control the substrate temperature during processing, a backside gas is provided between the support surface of the ceramic body and the substrate via backside gas passages formed through the ceramic body. Generally, the backside gas fills the interstitial area between the ceramic body and the substrate, thus providing a heat transfer medium that enhances the rate of heat transfer between the substrate and the substrate support.

### SUMMARY

Flow enhancement plugs and electrostatic chucks having the same are disclosed herein that that inhibit gas light-up while providing excellent flow conductance for the delivery of backside gases to the substrate support surface of the electrostatic chuck. The flow enhancement plugs advantageously prevents line of sight passage through the plug. The flow enhancement plugs described herein have high conductance flow structures selected from one, two or all of a network of engineered gas passages, external gas passages and internal gas passages. As a result, the high conductance flow structures of the flow enhancement plugs disclosed herein beneficially have a conductance that is much higher than conventional porous plug.

In one example, an electrostatic chuck is provided. The electrostatic chuck includes a chuck body having a chucking electrode disposed between a substrate support surface and a bottom surface. The chuck body has a cavity open to the bottom surface and at least one backside gas passage extending from the cavity to the substrate support surface. A plug is disposed in the cavity. The plug has a passage extending between a top surface and a bottom surface of the plug body. The passage has a length greater than a distance defined between the top and bottom surfaces of the plug.

In one example, the passage is part of a network of engineered gas passages extending between the top and bottom surfaces of the body.

In another example, the passage is formed on an external surface of the body. The passages is generally open laterally in a radial direction through the sidewall of the body.

In another example, the passage is formed on below a sidewall of the body (i.e., completely within the body). The internal passages may optionally be grouped in inner and outer passages.

In yet another example, an electrostatic chuck is provided that includes a plug disposed in a cavity of an electrostatic chuck. The plug has an engineered predefined network of passages extending between a top surface and a bottom surface of the plug. Each passage of the network of passages has a tortuous path through the plug that prevents a line of sight opening from being formed between the top and bottom surfaces of the chuck body. The chuck body also includes a chucking electrode disposed between a substrate support surface and a bottom surface. The chuck body has at least one backside gas passage extending from the cavity to a substrate support surface of the electrostatic chuck.

### BRIEF DESCRIPTION OF THE DRAWINGS

So that the manner in which the above recited features of the present disclosure can be understood in detail, a more particular description of the implementations, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 is a schematic view of a process chamber including a substrate support pedestal having a flow enhancement plug.

FIG. 2 is a partial cross-sectional view of the substrate support pedestal illustrating the flow enhancement plug disposed in an electrostatic chuck.

FIG. 3 is a schematic isometric view the flow enhancement plug shown in FIG. 2 illustrating an exterior flow passage.

FIGS. 4-5 are schematic isometric views of various examples of flow enhancement plugs having exterior gas flow passages that may be utilized in the electrostatic chuck illustrated in FIG. 2.

FIGS. 6-8 are side, top and bottom views of the flow enhancement plug illustrated in FIG. 3.

FIG. 9 is a partial sectional view of the flow enhancement plug illustrated in FIG. 6.

FIGS. 10-12 are side, top and bottom views of another example of a flow enhancement plug that may be utilized in the electrostatic chuck illustrated in FIG. 2.

FIGS. 13-14 are schematic partial see-through views of the flow enhancement plug illustrated in FIG. 10 illustrating inner and outer gas flow passages.

FIG. 15 is a schematic sectional view a flow enhancement plug having engineered predefined gas passages that may be utilized in the electrostatic chuck illustrated in FIG. 2.

FIGS. 16-21 are schematic top views of various examples of the flow enhancement plug illustrated in FIG. 15.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Described herein are flow enhancement plugs for electrostatic chucks that inhibit gas light-up while providing excellent flow conductance for the delivery of backside gases to the substrate support surface of the electrostatic chuck. The flow enhancement plugs includes at least one passage that prevents line of sight through the plug. In most examples, the flow enhancement plugs includes a plurality or network of gas passages, each of which have a length greater than a distance defined between the top and bottom surfaces of the plug. The gas passages may reside wholly within the plug, on the exterior surface of the plug, and/or be a network of engineered predefined passages. The engineered predefined passages are fabricated in a manner that forms an as-designed predefined structure that can be repeatedly manufactured plug to plug without the randomness of gas passages associated with sintered porous plugs commonly utilized in conventional electrostatic chucks. Engineered predefined passages may be fabricated, for example, by additive or subtractive manufacturing techniques. The gas passages have a high conductance as compared to conventional porous plugs, which improves temperature control of the substrate. Moreover, the large sectional area of each gas passage (compared to the interstitial gas passages of conventional porous plugs) is less prone to clogging or release of trapped particulate, thus advantageously providing uniform performance over the service life of the electrostatic chuck.

Some new semiconductor manufacturing processes utilize very high radio frequency (RF) power to generate plasma. The high RF power increases the RF currents and total voltages applied to the electrostatic chuck. In addition, some new plasma etch processes require significantly lower RF frequencies (e.g., 2 MHz or lower) than previously utilized. The lower RF frequencies cause an increase in the RF voltage applied across the ceramic body of the electrostatic chuck. The high voltage applied across the ceramic body may cause electrical discharge (i.e., arcing) between the substrate and the baseplate, and may cause ignition of the heat transfer gas (e.g., He) in the backside gas passages. This phenomenon is also commonly referred to as gas light-up.

In conventional electrostatic chucks, the backside gas passages often are fitted with a porous plug. The porous plug eliminates the long line of sight distance between the substrate and the baseplate that could enable gas light-up, while still allowing backside gas to flow to the interstitial space present between the ceramic body and substrate. However, the flow of backside gas through different porous plugs is unpredictable, making chamber to chamber process matching and temperature control challenging. Moreover, porous plugs are also susceptible to clogging, which can diminish the performance of the electrostatic chuck. In extreme cases, particulate within the porous plug may be released into the processing chamber where the particulate becomes a contaminant that could undesirably reduce product yield.

Thus, there is a need for an electrostatic chuck having an improved light-up resistant plug fitted in the backside gas passages.

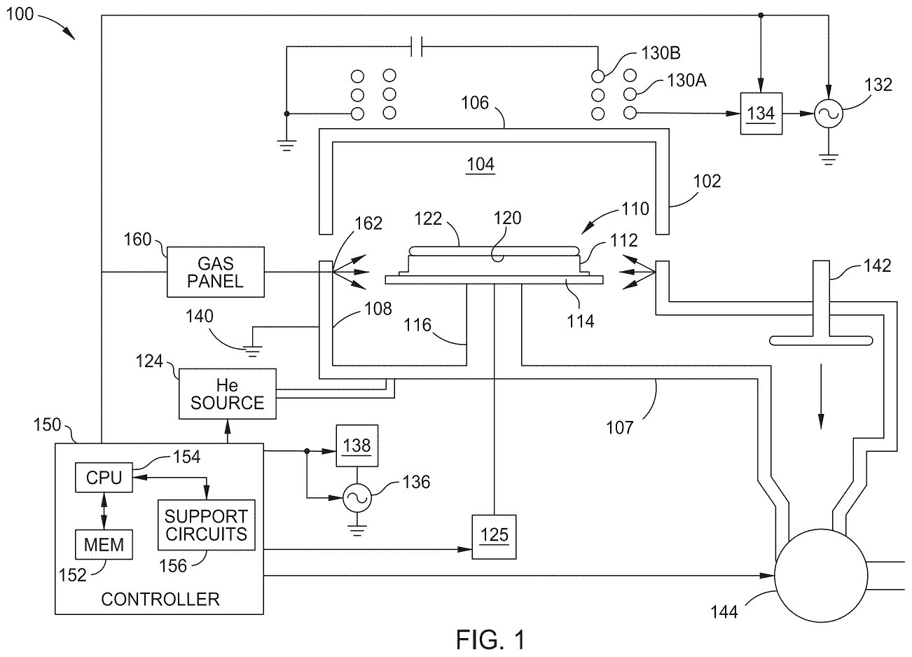

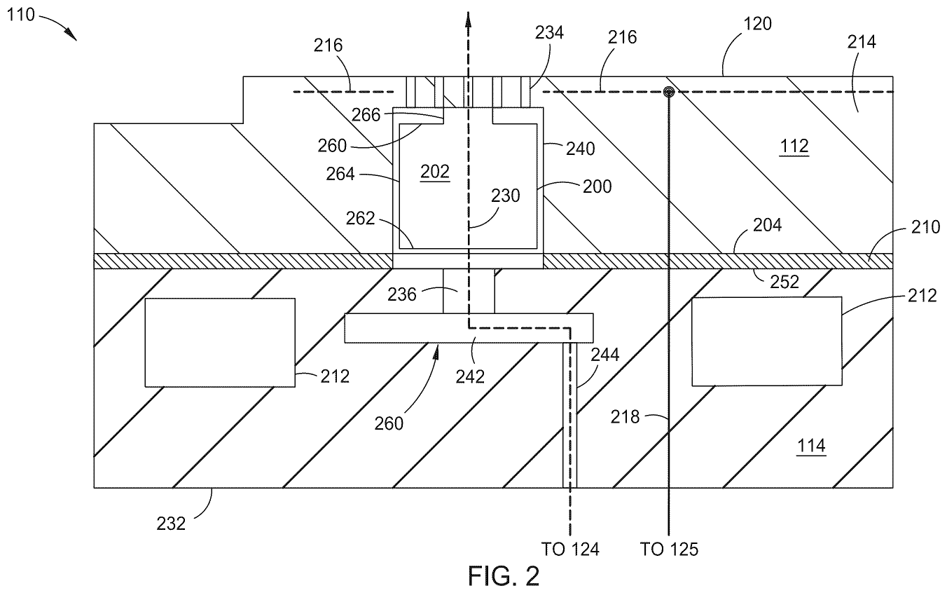

Turning now to FIG. 1, a schematic diagram of a process chamber 100 including a substrate support pedestal 110 having a flow enhancement plug is illustrated. Details of the flow enhancement plug are later provided beginning with the description of FIG. 2. Continuing to refer to FIG. 1, the process chamber 100 includes a chamber body 102, which defines a processing volume 104. The substrate support pedestal 110 is positioned within the processing volume 104. The chamber body 102 includes a lid 106, a chamber bottom 107, and one or more chamber walls 108. The lid 106 can be composed of a dielectric material.

The substrate support pedestal 110 includes an electrostatic chuck 112 disposed on a cooling base 114. The electrostatic chuck 112 includes a flow enhancement plug as later shown in FIG. 2. The substrate support pedestal 110 is generally supported above the chamber bottom 107 of the process chamber 100 by a pedestal support 116 coupled to the cooling base 114. The substrate support pedestal 110 is fastened to the pedestal support 116 such that the substrate support pedestal 110 can be removed from the pedestal support 116, refurbished, and re-fastened to the pedestal support 116. The pedestal support 116 is sealed to the cooling base 114 to isolate various conduits and electrical leads disposed therein from the process environment within the process chamber 100. Alternatively, the electrostatic chuck 112 and cooling base 114 maybe disposed on an insulating plate that is attached to a ground plate or chassis. Further, the ground plate may be attached to one or more of the lid 106, the chamber bottom 107, and the one or more chamber walls 108.

The electrostatic chuck 112 includes a substrate support surface (e.g., support surface) 120 for supporting a substrate, for example, a substrate 122, for example, a semiconductor substrate. The temperature of the substrate 122 is controlled by controlling the temperature of the electrostatic chuck 112. To promote heat exchange between the substrate 122 and the support surface 120 of the electrostatic chuck 112, a backside gas (e.g., a heat transfer gas, such as helium (He), nitrogen (N), argon (Ar) or other inert or otherwise suitable gas) may be provided by a backside gas source 124 to a plenum formed by the interstitial space defined between the substrate 122 and the support surface 120 of the electrostatic chuck 112. The backside gas facilitates heat transfer between the substrate 122 and the substrate support pedestal 110 to control the temperature of the substrate 122 during processing. The electrostatic chuck 112 may include one or more heaters. For example, the heaters may be electrical heaters or the like. The electrostatic chuck 112 may include one or more electrodes, which may be coupled to a power supply 125.

The process chamber 100 further includes at least an inductive coil antenna segment 130A and a conductive coil antenna segment 130B, both positioned exterior to the lid 106. The inductive coil antenna segment 130A and the conductive coil antenna segment 130B are each coupled to a radio-frequency (RF) source 132 that produces an RF signal. The RF source 132 is coupled to the inductive coil antenna segment 130A and to the conductive coil antenna segment 130B through a matching network 134. The substrate support pedestal 110 is also coupled to an RF source 136 that produces an RF signal. The RF source 136 is coupled to the substrate support pedestal 110 through a matching network 138. The one or more chamber walls 108 can be conductive and connected to an electrical ground 140. Alternatively, the process chamber 100 may be configured as a capacitively coupled plasma reactor.

The pressure within the processing volume 104 of the process chamber 100 is controlled using a throttle valve 142 situated between the process chamber 100 and a vacuum pump 144. The temperature at the surface of the one or more chamber walls 108 is controlled using liquid-containing conduits (not shown) that are located in the one or more chamber walls 108 of the process chamber 100.

A system controller 150 is coupled to the various components of the process chamber 100 to facilitate control of the substrate processing process. The system controller 150 includes memory 152, a central processing unit (CPU) 154, and support circuits (or I/O) 156. Software instructions and data can be coded and stored within the memory for instructing the CPU. The system controller 150 can communicate with one or more of the components of the process chamber 100 via, for example, a system bus. A program (or computer instructions) readable by the system controller 150 determines which tasks are performable on a substrate. In some aspects, the program is software readable by the system controller 150. Although a single system controller 150 is shown, it should be appreciated that multiple system controllers can be used with the aspects described herein.

In an etching operation, the substrate 122 is placed on the support surface 120 of the substrate support pedestal 110 and gaseous components are supplied from a gas panel 160 to the process chamber 100 through entry ports 162 to form a gaseous mixture in the processing volume 104 of the process chamber 100. The gaseous mixture in the processing volume 104 is ignited into a plasma in the process chamber 100 by applying RF power from the RF sources 132, 136 respectively to the inductive coil antenna segment 130A, the conductive coil antenna segment 130B and to the substrate support pedestal 110. Additionally, chemically reactive ions are released from the plasma and strike the substrate 122, thereby removing exposed material from the substrate's surface. It should be noted that the process chamber 100 may alternatively be configured to perform implantation, anneal, deposition or other type of semiconductor fabrication processes.

FIG. 2 is a partial cross-sectional view of the substrate support pedestal 110 illustrating one example of a flow enhancement plug 200. It is to be noted that the flow enhancement plug 200 does not rely on porosity for the delivery of backside gas flow through the plug 200. Although a body 202 of the plug 200 may be porous, the body 202 is typically solid. In the optional instance wherein the body 202 of the plug 200 is sintered or otherwise porous, gas flow through the body 202 is predominantly routed through the flow gas passages formed in the body 202, as compared to any gas that might flow through the porosity of the material from which the body 202 is fabricated. As discussed above, the substrate support pedestal 110 includes the cooling base 114 secured to the electrostatic chuck 112 by a bond layer 210.

The bond layer 210 comprises one or more materials such as an acrylic or silicon-based adhesive, epoxy, neoprene based adhesive, an optically clear adhesive such as a clear acrylic adhesive, or other suitable adhesive materials.

The cooling base 114 is generally fabricated from a metallic material such as stainless steel, aluminum, aluminum alloys, among other suitable materials. Further, the cooling base 114 includes one or more cooling channels 212 disposed therein that circulate a heat transfer fluid to maintain thermal control of the substrate support pedestal 110 and the substrate 122 disposed thereon during processing.

The electrostatic chuck 112 is generally circular in form but can alternatively comprise other geometries to accommodate non-circular substrates. For example, the electrostatic chuck 112 may comprise a square or rectangular substrate when used in processing glass, ceramic or plastic substrates for flat panels displays and solar panels. The electrostatic chuck 112 generally includes a chuck body 214 including one or more electrodes 216. The electrodes 216 are comprised of an electrically conductive material such as copper, graphite, tungsten, molybdenum and the like. Various implementations of electrode structures include, but are not limited to, a pair of coplanar D-shaped electrodes, coplanar interdigital electrodes, a plurality of coaxial annular electrodes, a singular, circular electrode or other structure. The electrodes 216 are coupled to the power supply 125 (shown in FIG. 1) by an electrical power feed through 218 disposed in the substrate support pedestal 110. The power supply 125 may drive the electrode 216 with a positive or negative voltage. For example, the power supply 125 may drive the electrode 216 with a voltage of about −1000 volts or a voltage of about 2500 volts. Alternatively, other negative voltages or other positive voltages may be utilized.

The chuck body 214 of the electrostatic chuck 112 can be fabricated from a ceramic material. For example, the chuck body 214 of the electrostatic chuck 112 may be fabricated from a low resistivity ceramic material, for example, a material having a resistivity between about 1×E⁹ to about 1×E¹¹ ohm-cm. Examples of low resistivity materials include ceramics such as alumina doped with titanium oxide or chromium oxide, doped aluminum oxide, doped boron-nitride and the like. Other materials of comparable resistivity, for example, aluminum nitride, may also be used. Such ceramic materials having relatively low resistivity generally promote a Johnsen-Rahbek attractive force between the substrate and electrostatic chuck 112 when power is applied to the electrodes 216. Alternatively, a chuck body 214 comprising ceramic materials having a resistivity equal to or greater than 1×E¹¹ ohms-cm may also be used. Further, the chuck body 214 of the electrostatic chuck 112 may be fabricated from an aluminum oxide. The aluminum oxide can have high resistivity and be used in Coulombic mode.

During operation, an electrical field generated by driving the electrodes 216 holds the substrate 122 on the support surface 120 with a clamping force. Backside gas, such as helium, nitrogen argon or other suitable base, is introduced from the backside gas source 124 to the interstitial defined between the substrate 122 and the support surface 120 of the electrostatic chuck 112 to aid in the control of the temperature of the substrate 122 retained by the electrostatic chuck 112.

The backside gas is routed through the substrate support pedestal 110 via one or more backside gas flow passages illustrated by dashed line 230 in FIG. 2. Further, while a single gas flow passage 230 is illustrated in FIG. 2, the substrate support pedestal 110 may include multiple backside gas flow passages 230. The backside gas flow passage 230 extends from the support surface 120 of the chuck body 214 to a bottom surface 232 of the cooling base 114. A portion of the backside gas flow passage 230 that resides in the chuck body 214 includes the cavity 240 formed in a bottom surface 204 of the chuck body 214 and a plurality of gas passages 234 that have top ends that exit the support surface 120 of the chuck body 214. Bottom ends of the plurality of gas passages 234 open into the cavity 240.

A portion of the backside gas flow passage 230 that resides in the cooling base 114 includes one or more cooling base gas passages 270. The cooling base gas passages 270 may include a distribution plenum 242, one or more feed holes 236, and a feed passage 244. The feed passage 244 exits the bottom surface 232 of the cooling base 114, and couples the distribution plenum 242 to the backside gas source 124. The one or more feed holes 236 are open to the distribution plenum 242 and exit a top surface 252 of the cooling base 114 in alignment with the cavity 240 formed in electrostatic chuck 112.

The portion of the backside gas flow passage 230 that resides in the cavity 240 of the electrostatic chuck 112 is also routed through the flow enhancement plug 200. The flow enhancement plug 200 may be bonded, press fit, or otherwise secured in the cavity 240. Alternatively, packing material, such as a polytetrafluoroethylene tape or the like, may be disposed between the flow enhancement plug 200 and the sidewalls of the cavity 240. The flow enhancement plug 200 may be fabricated from a dielectric material, such as a plastic or ceramic. In one example, the flow enhancement plug 200 is fabricated from polytetrafluoroethylene, polyaryletherketone or other suitable high dielectric strength plastic. In other examples, the flow enhancement plug 200 is fabricated from AlO₂, AlN or other suitable ceramic. Optionally, the material of the flow enhancement plug 200 may be porous. The flow enhancement plug 200 can be any suitable shape. In some implementations, the flow enhancement plug 200 has a cylindrical shape. Other suitable shapes include t-shaped, tapered, and rectangular.

The body 202 of the flow enhancement plug 200 generally includes a top surface 260, a sidewall 264, and a bottom surface 262. The sidewall 264 generally defines the outer lateral extends of the body 202, and in one example, is the outer diameter of the body 202. The shape and size of the sidewall 264 of the flow enhancement plug 200 is selected to fit within the cavity 240. The top surface 260 faces the upper surface of the cavity 240 through which the passages 234 are formed. The top surface 260 may also include a boss 266 to space the top surface 260 from the passages 234. The boss 266 creates a small plenum between the top surface 260 that promotes the flow conductance of gas out of the body 202 and into the passages 234. The bottom surface 254 of the flow enhancement plug 200 faces the top surface 252 of the cooling base 114 through a gap formed in bond layer 210. The bottom surface 254 of the flow enhancement plug 200 also faces and is aligned with at least one or more of the feed holes 236 of the cooling base gas passages 270 of the cooling base 114.

The flow enhancement plug 200 generally includes one or more backside gas flow passages extending between the top and bottom surfaces 260, 262 of the plug body 202 to facility the flow of backside gas to the passages 234 from which the backside gas can be provided to the substrate support surface 120 of the electrostatic chuck 112. The one or more backside gas flow passages may be formed completely enclosed within the plug body 202, and/or be formed in the sidewall 264 of the plug body 202 such that the gas flow passage is open to the sidewalls of the cavity 240.

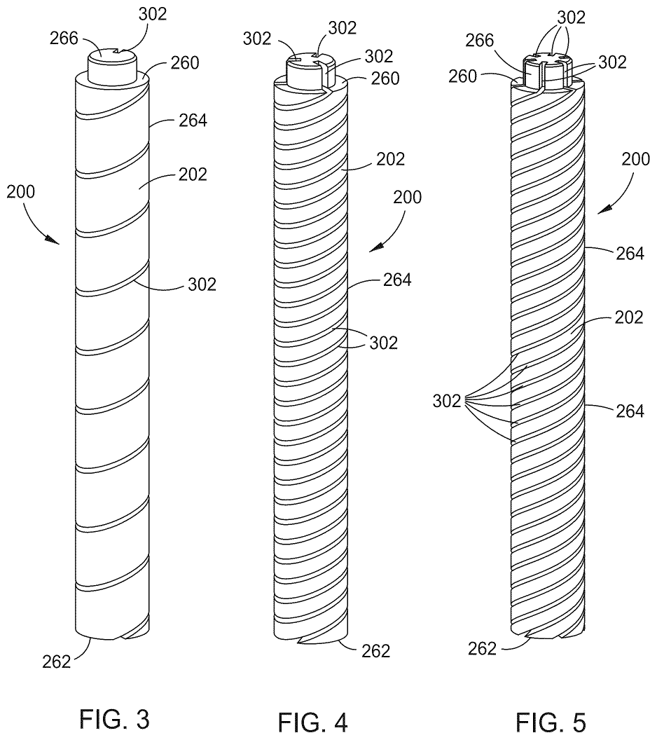

FIG. 3 is a schematic isometric view the flow enhancement plug 200 shown in FIG. 2 illustrating one example of an internal flow passages 302 formed on an exterior surface (i.e., sidewall 264) of the plug body 202. In FIG. 3, the flow enhancement plug 200 has a single exterior internal flow passages 302 formed in the sidewall 264 of the plug body 202 that is open to sidewalls of the cavity 240 upon installation in the electrostatic chuck 112 (ignoring packing materials and/or adhesives, if present). One end of the internal flow passages 302 is open to the top surface 260 of the plug body 202, while a second end of the internal flow passages 302 is open to the bottom surface 262 of the plug body 202, such that gas may flow through the passage 302 between the top and bottom surfaces 260, 262. The internal flow passages 302 may be arranged in a helical geometry, or have another suitable geometry.

The plug body 202 may alternatively have two or more flow gas passages 302. For example, the plug body 202 illustrated in FIG. 4 has three flow passages 302, while the plug body 202 illustrated in FIG. 5 has six flow passages 302.

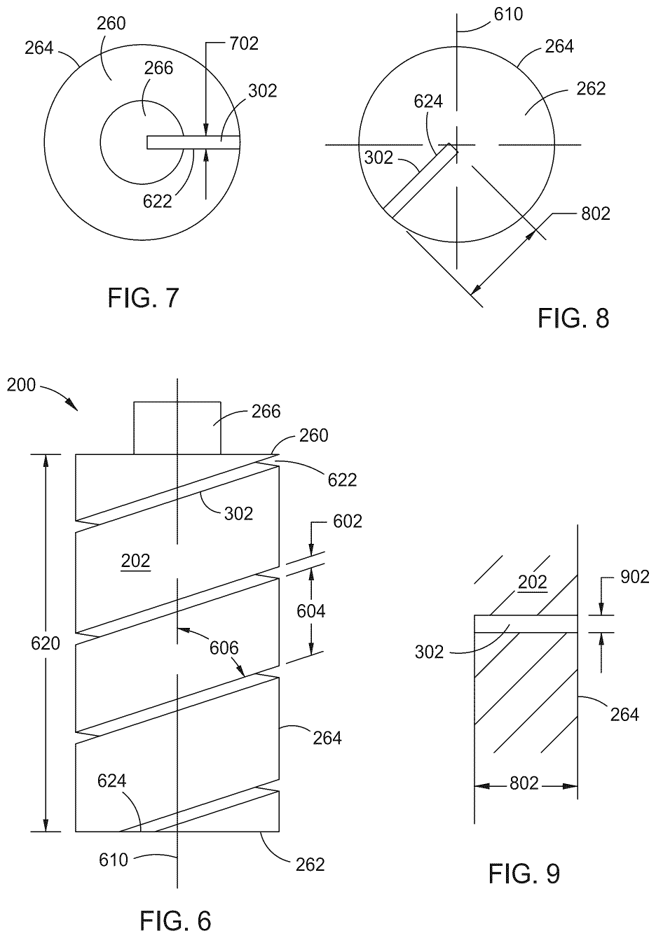

FIGS. 6-8 are side, top and bottom views illustrating additional details of the flow enhancement plug 200 shown in FIG. 3. The internal flow passages 302 illustrated in FIG. 6 has multiple turns around the plug body 202. The internal flow passages 302 may have any number of turns greater than zero. For example, the internal flow passages 302 may have 1/32, 1/16, ⅛, ½, ¾ or a full turn. In another example, the internal flow passages 302 may have more than 1 turn, for example 3 or more turns. Each turn of the internal flow passages 302 defines a pitch 604. The pitch 604 may range between about 2 mm to about 10 mm, or have another pitch. The internal flow passages 302 is also inclined at an angle 606 relative to a centerline 610 of the plug body 202. The angle 606 is generally an acute angle, for example in the range of 60 degrees to about 85 degrees.

The internal flow passages 302 has a first end 622 and a second end 624. The first end 622 is open to the top surface 260 as more clearly illustrated in FIG. 7, while the second end 624 is open to the bottom surface 262 as more clearly illustrated in FIG. 8. The internal flow passages 302 has a length defined between the ends 622, 624 than is longer than a distance 620 defined between the top and bottom surfaces 260, 262. The distance 620 is measured in a direction parallel to the centerline 610. In one example, a ratio of the length defined between the ends 622, 624 to the distance 620 is at least 1.5 mm.

The internal flow passages 302 has a height 602 (shown in FIG. 6), a width 702 (shown in FIG. 7), and a depth 802 (as shown in FIG. 8). The width 702 may range from about 0.1 mm to about 2.0 mm. The depth 802 may be expressed as R−x, where R is the radius of the body 202 (at the sidewall 264) and x is between about 1.0 mm to about 5.0 mm. In one example, the depth 802 extends from the sidewall 264 to almost the centerline 610 of the body 202. The height 602 is equal to the cosine of the angle 606 times the projected height (shown as 902 in FIG. 9) of the passage 302.

Referring additionally to the partial sectional view of the flow enhancement plug 200 illustrated FIG. 9, the projected height 902 is measured in a direction parallel with the centerline 610 (generally the vertical direction). The projected height 902 can be selected to reduce the probability of light-up for expected voltages, backside gas composition, and backside gas pressure. The projected height 902 is about 0.1 mm to about 0.5 mm. In one example, the projected height 902 (in mm) may be expressed as Min[(2.6/Pmax), (100*H/Vmax)], where Pmax is the maximum pressure in Torr, Vmax is the maximum voltage in Volts, and H is the dimension 620 in mm).

In yet other examples, the open area provided by the external flow passage(s) 302 have an open area of at least 10 percent as measured in a slice of the body 202 taken perpendicular to the centerline 610. In one example, the flow passages 302 to have an open area of between about 10 percent to 60 percent as measured in a slice of the body 202 taken perpendicular to the centerline 610. The high open area enables the flow enhancement plug 200 to have superior conductance as compared to conventional sintered plugs.

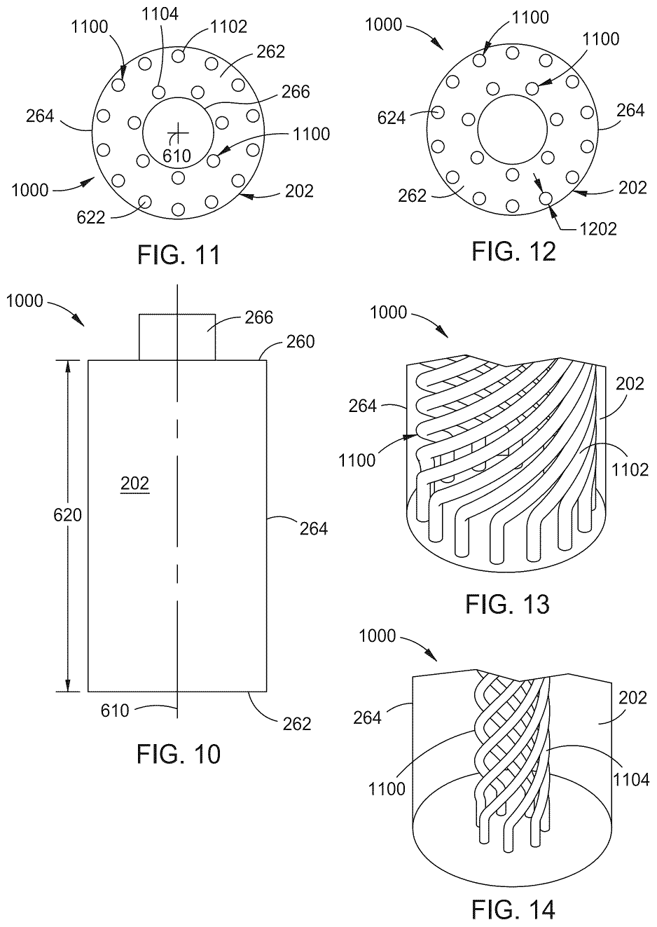

FIGS. 10-12 are side, top and bottom views of another example of a flow enhancement plug 1000 that may be utilized in the electrostatic chuck 112 illustrated in FIG. 2 in place of the plug 200. The flow enhancement plug 1000 is generally constructed the same as the plug 200, except that flow enhancement plug 1000 alternatively, or additionally, includes one or more internal flow passage 1100 completely within (i.e., spaced inward form the sidewall 264) of the plug body 202. The flow enhancement plug 1000 may have has a single internal flow passage 1100 or a plurality of internal flow passages 1100. In the example depicted in FIGS. 10-12, the internal flow passages 1100 are arranged in two or more groupings. For example, the internal flow passages 1100 may be arranged in a first group 1102 of internal flow passages 1100 and a second group 1104 of internal flow passages 1100. The internal flow passages 1100 within each group 1102, 1104 may be arranged on a common radius from the centerline 610 of the body 202 of the flow enhancement plug 1000, such that the internal flow passages 1100 of the first group 1102 resides on a common diameter that is radially outward of a common diameter upon which the internal flow passages 1100 of the second group 1104 reside. In one example, a number of internal flow passages 1100 of the first group 1102 is more than a number of internal flow passages 1100 of the second group 1104.

One end of the internal flow passages 1100 is open to the top surface 260 of the plug body 202, while a second end of the internal flow passages 1100 is open to the bottom surface 262 of the plug body 202 such that gas may flow between the top and bottom surfaces 260, 262. The internal flow passages 1100 may be arranged in a helical geometry, or have another suitable geometry.

FIGS. 13-14 are schematic partial see-through views of the flow enhancement plug 1000 illustrating inner and outer groups 1102, 1104 of internal gas flow passages 1100. Each of the internal flow passages 1100 has multiple turns within the body 202. The internal flow passages 1100 may have any number of turns greater than zero. For example, the internal flow passages 1100 may have 1/32, 1/16, ⅛, ½, ¾ or a full turn. In another example, the internal flow passages 1100 may have more than 1 turn, for example 3 or more turns.

The spacing between the turns of adjacent internal flow passages 1100 defines a pitch, such as illustrated by the pitch 604 shown in FIG. 6. The pitch may range between about 2 mm to about 10 mm, or have another pitch. The pitch of internal flow passages 1100 comprising the first group 1102 may be greater than a pitch of the internal flow passages 1100 comprising the second group 1104. The internal flow passages 1100 may also be inclined at an angle (606 such as shown in FIG. 6) relative to a centerline 610 of the body 202. The angle is generally an acute angle, for example in the range of about 60 to about 85 degrees.

The internal flow passages 1100 has a first end 622 and a second end 624. The first end 622 is open to the top surface 260 as more clearly illustrated in FIG. 11, while the second end 624 is open to the bottom surface 262 as more clearly illustrated in FIG. 12. The internal flow passages 1100 has a length defined between the ends 622, 624 than is longer than a distance 620 defined between the top and bottom surfaces 260, 262. The distance 620 is measured in a direction parallel to the centerline 610. The length of the internal flow passages 1100 of the first group 1102 may be longer than the length of the internal flow passages 1100 of the second group 1104.

Each of the internal flow passages 1100 have diameter 1202 that may range from about 0.1 mm to about 1.0 mm. Each internal flow passage 1100 of the flow enhancement plug 1000 may also have a projected height that is defined the same of the projected height 902 as shown and described with reference to FIG. 9.

In yet other examples, the open area provided by the internal flow passage(s) 1100 have an open area of at least 10 percent as measured in a slice of the body 202 taken perpendicular to the centerline 610. In one example, the flow passages 1100 to have an open area of between about 10 percent to 60 percent as measured in a slice of the body 202 taken perpendicular to the centerline 610. The high open area enables the flow enhancement plug 200 to have superior conductance as compared to conventional sintered plugs.

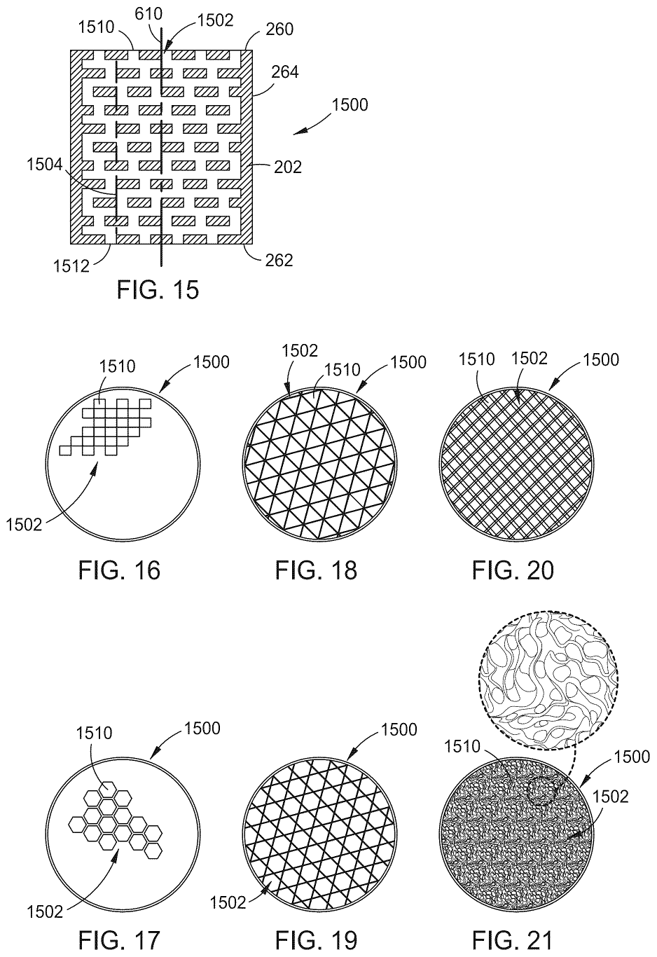

FIG. 15 is a schematic sectional view a flow enhancement plug 1500 having engineered predefined gas passages 1502 that may be utilized in the electrostatic chuck 112 illustrated in FIG. 2 in place of the plug 200. The flow enhancement plug 1500 is generally constructed the same as the plug 200, except that flow enhancement plug 1500 includes an engineered predefined network of passages 1502 extending between outlets 1510 formed in a top surface 260 and inlets 1512 from in a bottom surface 262 of the plug body 202. Each passage 1502 of the network of passages has a tortuous path through the plug body 202 that prevents a line of sight opening from being formed between the top and bottom surfaces 260, 262 in a direction parallel to the centerline 610 of the plug body 202.

The engineered predefined passages 1502 are fabricated in a manner that forms an as-designed predefined structure that can be repeatedly manufactured plug to plug without the randomness of gas passages associated with sintered porous plugs commonly utilized in conventional electrostatic chucks. The gas passages 1502 have a high conductance as compared to conventional porous plugs, which improves temperature control of the substrate. Moreover, the large sectional area of each gas passage 1502 (compared to the interstitial gas passages of conventional porous plugs) is less prone to clogging or release of trapped particulate, thus advantageously providing uniform performance over the service life of the electrostatic chuck 112. In one example, the flow enhancement plug 1500 has a pressure drop of less than about 0.1 Torr, such as less than 1.0 Torr, when a 1.0 sccm flow of He is passed through the plug in a direction parallel with the centerline 610 of the plug body 202.

In one example, the flow enhancement plug 1500 may optionally include one or more external flow passages 302. In another example, the flow enhancement plug 1500 may optionally include one or more internal flow passages 1100. In still another example, the flow enhancement plug 1500 may optionally include one or more external flow passages 302 and one or more one or more internal flow passages 1100.

Optionally, one or more walls 1504 may be formed within the body 202, extending between the top and bottom surfaces 260, 262. The wall 1504 fluidly isolates some of the passages 1502 from other passages 1502 such that the volume of flow though the body 202 is separated into separate zones that are laterally isolated from each other. In one example, at least two zones of passages 1502 may different volumetric rates of flow. Thus, the center to edge, or azimuthal profile of flow exiting the outlets 1510 formed in the top surface 260 of the body 202 may be set as desired.

The flow passages 1502 are generally formed by additive or subtractive manufacturing techniques. The additive or subtractive manufacturing techniques enable the flow passages 1502 to have an open area of at least 10 percent as measured in a slice of the body 202 taken perpendicular to the centerline 610. In one example, the flow passages 1502 to have an open area of between about 10 percent to about 60 percent as measured in a slice of the body 202 taken perpendicular to the centerline 610. The high open area enables the flow enhancement plug 1500 to have superior conductance as compared to conventional sintered plugs.

FIGS. 16-21 are schematic top views of various examples of the flow enhancement plug 1500 illustrated in FIG. 15. In FIG. 16, the flow passages 1502 are shown configured as a regular (i.e., evenly spaced) mesh grid. The mesh grid may have an X/Y orientation. The orientation of the mesh generally changes in the X or Y direction, or rotates at different elevations within the body 202 to prevent a line of sight opening from being formed through the body 202 by the flow passages 1502.

In FIG. 17, the flow passages 1502 are shown configured as honeycomb cells. The orientation of the honeycomb cells generally changes in the X or Y direction, or rotates at different elevations within the body 202 to prevent a line of sight opening from being formed through the body 202 by the flow passages 1502.

In FIG. 18, the flow passages 1502 are shown configured within a triangular grid. The orientation of the triangular grid generally changes in the X or Y direction, or rotates at different elevations within the body 202 to prevent a line of sight opening from being formed through the body 202 by the flow passages 1502.

In FIG. 19, the flow passages 1502 are shown configured within a tri-hexagonal grid. The orientation of the tri-hexagonal grid generally changes in the X or Y direction, or rotates at different elevations within the body 202 to prevent a line of sight opening from being formed through the body 202 by the flow passages 1502.

In FIG. 20, the flow passages 1502 are shown configured within a wire mesh. The orientation of the wire mesh generally changes in the X or Y direction, or rotates at different elevations within the body 202 to prevent a line of sight opening from being formed through the body 202 by the flow passages 1502.

In FIG. 21, the flow passages 1502 are shown configured within a gyroid. The orientation of the gyroid generally changes in the X or Y direction, or rotates at different elevations within the body 202 to prevent a line of sight opening from being formed through the body 202 by the flow passages 1502.

Thus, flow enhancement plugs for electrostatic chucks have been disclosed above that inhibit gas light-up while providing excellent flow conductance for the delivery of backside gases to the substrate support surface of the electrostatic chuck. The flow enhancement plugs advantageously prevents line of sight passage through the plug. The flow enhancement plugs described herein have high conductance flow structures selected from one, two or all of a network of engineered gas passages, external gas passages and internal gas passages. The high conductance flow structures generally have a conductance that is much higher than conventional porous plug that can be repeatedly manufactured plug to plug without the randomness of gas passages associated with sintered porous plugs commonly utilized in conventional electrostatic chucks. The predictable and repeatable flow structures provide improved temperature control and longer service time between cleans, thus advantageously providing uniform and robust performance over the service life of the electrostatic chuck.

1. An electrostatic chuck comprising:
a chuck body having a chucking electrode disposed between a substrate support surface and a bottom surface, the chuck body having a cavity open to the bottom surface and at least one body gas passage extending from the cavity to the substrate support surface; and
a plug disposed in the cavity, the plug having a top surface, a bottom surface, and a plug passage, the plug passage extending between the top and bottom surfaces of the plug, the plug passage having a length greater than a distance defined between the top and bottom surfaces of the plug.

2. The electrostatic chuck of claim 1, wherein the plug passage is open to an outer diameter sidewall of the plug.

3. The electrostatic chuck of claim 2, wherein the plug passage has a helical geometry.

4. The electrostatic chuck of claim 2, wherein the plug passage is one of a plurality of plug passages open to the outer diameter sidewall of the plug.

5. The electrostatic chuck of claim 2, wherein the plug passage has a width extending more than a third of a diameter of the outer diameter sidewall of the plug.

6. The electrostatic chuck of claim 1, wherein top surface of the plug includes a boss.

7. The electrostatic chuck of claim 1, wherein the plug is fabricated from a dielectric material.

8. The electrostatic chuck of claim 7, wherein the dielectric material is a plastic or ceramic.

9. The electrostatic chuck of claim 1, wherein the plug passage is spaced from an outer diameter sidewall of the plug.

10. The electrostatic chuck of claim 9, wherein the plug passage has a helical geometry.

11. The electrostatic chuck of claim 9, wherein the plug passage is one of a plurality of plug passages disposed below the outer diameter sidewall of the plug.

12. The electrostatic chuck of claim 11, wherein the plurality of plug passages includes a first group of interior passages disposed radially inward of a second group of interior plug passages.

13. The electrostatic chuck of claim 9, wherein top surface of the plug includes a boss, and wherein the plug passage exits the top surface of the plug between the boss and the outer diameter sidewall of the plug.

14. The electrostatic chuck of claim 11 further comprising:
an exterior plug passage extending between the top and bottom surfaces of the plug, the exterior plug passage having a length greater than a distance defined between the top and bottom surfaces of the plug, wherein the exterior plug passage is open to an outer diameter sidewall of the plug.

15. The electrostatic chuck of claim 1, wherein the plug has a centerline, and a height of the plug passage defined in a direction parallel to the centerline is less than 0.1 mm.

16. The electrostatic chuck of claim 1, wherein a pressure drop across the plug is less than about 1.0 Torr, when a 1.0 sccm flow of He is passed through the plug in a direction parallel with a centerline of the plug.

17. An electrostatic chuck comprising:
a chuck body having a chucking electrode disposed between a substrate support surface and a bottom surface, the chuck body having a cavity open to the bottom surface and at least one body gas passage extending from the cavity to the substrate support surface; and
a plug disposed in the cavity, the plug having a top surface, a bottom surface, and an engineered predefined network of plug passages, the engineered predefined network of plug passages extending between the top and bottom surfaces of the plug, each plug passage of the predefined network of plug passages having a tortuous path through the plug that prevents a line of sight opening from being formed between the top and bottom surfaces of the plug.

18. The electrostatic chuck of claim 17, wherein the plug is fabricated via additive manufacturing techniques.

19. The electrostatic chuck of claim 17, wherein the predefined network of plug passages exit the top surface of the plug in a tri-hexagonal, grid, honeycomb or gyroid arrangement.

20. The electrostatic chuck of claim 17, wherein the plug is fabricated from a dielectric material.

21. The electrostatic chuck of claim 20, wherein the dielectric material is a plastic or ceramic.

22. The electrostatic chuck of claim 17, wherein a pressure drop across the plug is less than about 1.0 Torr, when a 1.0 sccm flow of He is passed through the plug in a direction parallel with a centerline of the plug.
